(19) United States
(12) Patent Application Publication
(10) Pub. No.: US 2013/0146904 A1
(43) Pub. Date: Jun. 13, 2013

(54) Optoelectronic Structures with High Lumens Per Wafer

(71) Applicant: Cree, Inc., Durham, NC (US)

(72) Inventors: John Edmond, Durham, NC (US); David Todd Emerson, Chapel Hill, NC (US)

(73) Assignee: Cree, Inc., Durham, NC (US)

(21) Appl. No.: 13/693,776

(22) Filed: Dec. 4, 2012

Related U.S. Application Data
(60) Provisional application No. 61/567,799, filed on Dec. 7, 2011.

(51) Int. Cl. H01L 33/08

(52) U.S. Cl. CPC H01L 33/08
USPC 257/88

(57) ABSTRACT

An optoelectronic structure includes a wafer, a plurality of light emitting diode structures on a surface of the wafer, and a coating including a wavelength conversion material on the plurality of light emitting diode structures. The light emitting diode structures and the coating are configured to emit white light in response to electrical energy supplied to the light emitting diode structures. The light emitting diode structures from a single wafer are configured to generate an aggregate light output in excess of 800,000 lumens.

### CLAIM OF PRIORITY

The present application claims the benefit of and priority to U.S. Provisional Patent Application No. 61/567,799, filed Dec. 7, 2011, entitled “OPTOELECTRONIC STRUCTURES WITH HIGH LUMENS PER WAFER,” the disclosure of which is hereby incorporated herein by reference in its entirety.

### FIELD

The present invention relates to optoelectronic devices, and in particular relates to semiconductor wafers including optoelectronic devices fabricated thereon.

### BACKGROUND

Semiconductor light emitting devices (“LEDs”), such as light emitting diodes and laser diodes, are widely known solid-state lighting elements that are capable of generating light upon application of voltage thereto. Light emitting devices generally include a p-n junction, an anode ohmic contact for the p-type region of the device, and a cathode ohmic contact for the n-type region of the device. The device may be formed on a substrate, such as a sapphire, silicon, silicon carbide, gallium arsenide, gallium nitride, etc., substrate, or the device may not include a substrate. The semiconductor p-n junction may be fabricated, for example, from silicon carbide, gallium nitride, gallium phosphide, aluminum nitride and/or gallium arsenide-based materials and/or from organic semiconductor-based materials.

Semiconductor LEDs may be used in lighting/illumination applications, for example, as a replacement for conventional incandescent and/or fluorescent lighting. However, before semiconductor light emitting diodes can become a viable alternative to incandescent and/or fluorescent lighting, the capabilities of such devices must be increased to a point where the cost of the devices is justified.

The total amount of visible light generated by a light emitter is measured in lumens. The lumen is the SI derived unit of luminous flux, a measure of the total “amount” of visible light emitted by a source. Luminous flux differs from power (radiant flux) in that luminous flux measurements reflect the varying sensitivity of the human eye to different wavelengths of light, while radiant flux measurements indicate the total power of all light emitted, independent of the eye's ability to perceive it. The lumen (lm) is defined in relation to the candela (cd) as 1 lm=1 cd·sr. A full sphere has a solid angle of 4·π steradians, so a light source that uniformly radiates one candela in all directions has a total luminous flux of 1 cd·4πsr≈12.57 lumens.

Luminous efficacy, measured in lumens per watt (lm/W) is considered an important figure of merit for solid state white lighting devices. As the ratio of luminous flux to power, luminous efficacy is a measure of how efficiently a light source generates visible light. However, luminous efficacy does not take into account the cost of manufacturing the device itself, and thus may not provide a good basis for comparing how economically viable a particular device is from a manufacturing standpoint.

For general lighting applications, it is important for a lighting device to generate white light. Although it is possible to generate white light by combining light from several different color emitters (e.g., red, green and blue), such devices must be carefully designed so that light from different emitters is combined to obtain the desired optical characteristics. This requires careful design of the package and fixture, as well as careful control over the current supplied to each emitter. Such devices are also highly sensitive to changes in operating temperature, since different color emitters may have different temperature coefficients. Many solid state lighting applications therefore generate white light using single color LEDs combined with wavelength converting materials.

To generate white light from a single color LED, the light from the LED may be converted to white light by surrounding the LED with a wavelength conversion material, such as phosphor particles. The term “wavelength conversion material” is used herein to refer to any material that absorbs light at one wavelength and re-emits light at a different wavelength, regardless of the delay between absorption and re-emission and regardless of the wavelengths involved. Accordingly, the term “wavelength conversion material” may be used herein to refer to materials that are sometimes called fluorescent and/or phosphorescent and often referred to as “phosphors”. In general, phosphors absorb light having shorter wavelengths and re-emit light having longer wavelengths. As such, some or all of the light emitted by the LED at a first wavelength may be absorbed by the phosphor particles, which may responsively emit light at a second wavelength. For example, a blue emitting LED may be surrounded by a yellow phosphor, such as cerium-doped yttrium aluminum garnet (YAG). The resulting light, which is a combination of blue light and yellow light, may appear white to an observer.

Efforts have been made to integrate a semiconductor light emitting device with wavelength conversion material to provide a semiconductor light emitting apparatus. The wavelength conversion material may be coated on the LED itself, may be provided in a drop of material between the semiconductor LED and the dome of an LED (also referred to as a shell or lens) and/or may be provided remote from the semiconductor LED by providing wavelength conversion material inside, outside and/or within the dome of an LED and/or on/within another surface remote from the LED.

### SUMMARY

An optoelectronic structure according to some embodiments includes a wafer and a plurality of light emitting diode structures on a surface of the wafer. The light emitting diode structures have a common epitaxial structure. A coating including a wavelength conversion material is on the plurality of light emitting diode structures. The light emitting diode structures and the coating are configured to collectively emit white light in response to electrical energy supplied to the light emitting diode structures. The light emitting diode structures are configured to generate, when singulated, an aggregate light output in excess of 800,000 lumens.

The light emitting diode structures may be configured to generate an aggregate light output in excess of 825,000 lumens. In some embodiments, the light emitting diode structures may be configured to generate an aggregate light output in excess of 862,500 lumens. In further embodiments, the light emitting diode structures may be configured to generate an aggregate light output in excess of 1,000,000 lumens, and in still further embodiments in excess of 1,250,000 lumens.

The wafer may include an epitaxial growth wafer on which the common epitaxial structure of the plurality of light emitting diodes is formed. In some embodiments, the wafer may include an a carrier wafer on which the plurality of light emitting diodes are mounted.

The plurality of light emitting diode structures may include at least 7500 light emitting diode structures on the wafer, and in some embodiments at least 9500 light emitting diode structures on the wafer.

The plurality of light emitting diode structures may represent a device yield of at least about 70%, and in some embodiments at least about 87% on the wafer.

Each of the plurality of light emitting diode structures may emits light within a 4 step MacAdam ellipse of a point on a planekian locus in a two dimensional chromaticity space.

The plurality of light emitting diode structures may generate light having a color temperature greater than 4500K. In some embodiments, the plurality of light emitting diode structures may generate light having a color temperature less than 4500K.

The plurality of light emitting diode structures may have peripheral dimensions less than 1 mm×1 mm.

The plurality of light emitting diode structures may be configured to generate an aggregate light output in excess of 800,000 lumens at a drive current of 350 mA.

The wafer may have a diameter of at least about 100 mm, and in some embodiments a diameter of at least about 150 mm.

An optoelectronic structure according to further embodiments includes a wafer and

a plurality of light emitting diode structures on a surface of the wafer. The light emitting diode structures are configured to collectively emit an aggregate light output in excess of 800,000 lumens light at a chromaticity region that is within a 4 step MacAdam ellipse of a point on a planckian locus within a two dimensional chromaticity space with a color temperature between 2000K and 8000K in response to electrical energy supplied to the light emitting diode structures.

### BRIEF DESCRIPTION OF THE DRAWINGS

FIG. 1A is a plan view and FIG. 1B is a sectional view of an optoelectronic epiwafer in accordance with some embodiments.

FIG. 2 is a perspective view of a susceptor that can be used for epitaxial growth according to some embodiments.

FIG. 3 is a sectional view of the susceptor in FIG. 2, taken along section lines 3-3.

FIG. 4 is an exploded view of the susceptor in FIG. 2.

FIG. 5 is a plan view of a heat transfer plug used in the susceptor of FIG. 2.

FIG. 6A is a sectional view of the plug in FIG. 5, taken along section lines 6a-6a.

FIG. 6B is a sectional magnified view of a plug ridge shown in FIG. 6a.

FIG. 7 is a schematic illustration of a Group III nitride light emitting diode epitaxial structure according to some embodiments.

FIG. 8 is a schematic illustration of a Group III nitride light emitting diode epitaxial structure according to some embodiments.

FIG. 9 is a schematic illustration of a quantum well structure and a multi-quantum well structure according to additional embodiments.

FIG. 10 is a schematic illustration of a Group III nitride light emitting diode epitaxial structure according to further embodiments.

FIGS. 11A through 11D are sectional views of embodiments of an optoelectronic wafer including LED devices at fabrication steps according to some embodiments.

FIG. 12 is a sectional view of an LED chip having a textured surface for light extraction according to some embodiments.

FIGS. 13 and 14 are sectional views of optoelectronic wafers including LED devices according to further embodiments.

FIG. 15 is a graph of a 1931 CIE Chromaticity Diagram illustrating the location of the planckian locus,

### DETAILED DESCRIPTION

As noted above, luminous efficacy is a commonly used figure of merit for evaluating solid state white lighting devices. However, luminous efficacy does not take into account the cost of manufacturing the device itself, and thus may not provide a suitable basis for evaluating the economic viability of a particular device design.

The fabrication of semiconductor light emitting devices generally includes forming thin epitaxial layers on a substrate. The epitaxial layers define the structure of the active region of the light emitting device, that is, the region of the light emitting device that converts electrical energy into light.

Semiconductor substrates on which the epitaxial layers are formed are generally provided and processed in wafer form. Circular wafers provide a convenient, consistent and economical way of handling semiconductor materials.

The present inventors have appreciated that economic viability of a semiconductor based white light emitting device is directly related to the number of lumens that can be generated from a single wafer. Embodiments of the invention provide Group III-nitride epiwafers capable of generating in excess of 800,000 lumens per wafer for a 100 mm wafer. Stated differently, some embodiments of the invention provide a wafer including a sufficient number of yieldable white light emitting device precursor structures that, when energized, are capable of generating a white light output in excess of 800,000 lumens per wafer for a 100 mm wafer.

An optoelectronic structure according to some embodiments includes a wafer and a plurality of light emitting diode structures on a surface of the wafer, the light emitting diode structures including a common epitaxial structure. A coating including a wavelength conversion material is on the plurality of light emitting diode structures. The light emitting diode structures and the coating are configured to emit white light in response to electrical energy supplied to the light emitting diode structures.

The light emitting diode structures are configured to generate a light output in excess of 110 lumens of warm white (color temperature less than 4500K, for example about 3000 K) light at a drive current of 350 mA. In some embodiments, the light emitting diode structures are configured to generate an aggregate light output in excess of 115 lumens of warm white light at 350 mA. In further embodiments, the light emitting diode structures are configured to generate an aggregate light output in excess of 120 lumens of warm white light at 350 mA. The light emitting diode structures may have a peripheral dimension of less than 1 mm×1 mm. In some embodiments, the light emitting diode structures may have a peripheral dimension of about 0.85 mm×0.85 mm.

In some further embodiments, the light emitting diode structures are configured to generate a light output in excess of 125 lumens of cool white (color temperature greater than 4500K, for example about 6000 K) light at a drive current of 350 mA. In some embodiments, the light emitting diode structures are configured to generate an aggregate light output in excess of 135 lumens of cool white light at 350 mA. In further embodiments, the light emitting diode structures are configured to generate an aggregate light output in excess of 142 lumens of cool white light at 350 mA.

The wafer may include an epitaxial growth wafer on which the common epitaxial structure of the plurality of light emitting diodes is formed. In other embodiments, the wafer may include a carrier wafer on which the plurality of light emitting diodes are mounted,

The plurality of light emitting diode structures may include at least 7500 usable light emitting diode structures on a 100 mm diameter wafer. Moreover, the plurality of light emitting diode structures represents an average device yield of at least 70% on the wafer. In some embodiments, the plurality of light emitting diode structures may include at least 9500 usable light emitting diode structures on a 100 mm diameter wafer, representing a device yield of at least 87% on the wafer.

Warm white (about 3000 K) devices may have an average lumen output of 115 lumens. The 90th and 10th percentile distribution of lumens for yieldable devices may have a lumen distribution of +/−5% (from about 110 to about 120 lumens). Thus, a 100 mm wafer may yield at least about 825,000 lumens per 100 mm wafer of warm white LEDs, in some embodiments at least about 862,500 lumens per wafer per 100 mm wafer of warm white LEDs, and in still further embodiments at least about 1,000,000 lumens per wafer per 100 mm wafer of warm white LEDs.

Cool white (about 6000 K) devices may have an average lumen output of 135 lumens. The 90th and 10th percentile distribution of lumens for yieldable devices may have a lumen distribution of +/−5% (from about 128 to about 142 lumens). Thus, a 100 mm wafer may yield at least about 960,000 lumens per wafer per 100 mm wafer of cool white LEDs, in some embodiments at least about 1,000,000 lumens per wafer per 100 mm wafer of cool white LEDs, and in still further embodiments at least about 1,250,000 lumens per wafer per 100 mm wafer of cool white LEDs.

Increasing wafer size can produce more lumens per wafer. For example, a 150 mm wafer, which has an area about 2.25 times the area of a 100 mm wafer, may yield at least about 1,800,000 lumens per 150 mm wafer of warm white (about 3000 K) LEDs, in some embodiments at least about 1,900,000 lumens per wafer per 150 mm wafer of warm white LEDs, and in still further embodiments at least about 2,400,000 lumens per wafer per 100 mm wafer of warm white LEDs.

Cool white (about 6000 K) devices may have an average lumen output of 135 lumens. The 90th and 10th percentile distribution of lumens for yieldable devices may have a lumen distribution of +/−5% (from about 128 to about 142 lumens). Thus, a 150 mm wafer may yield at least about 2,000,000 lumens per wafer per 150 mm wafer of cool white LEDs, in some embodiments at least about 2,200,000 lumens per wafer per 150 mm wafer of cool white LEDs, and in still further embodiments at least about 2,500,000 lumens per wafer per 100 mm wafer of cool white LEDs.

Each of the plurality of light emitting diode structures emits light within a 4 step MacAdam ellipse of a point in a two dimensional chromaticity space.

One method for measuring the target emission for LEDs is by standard deviation from a target color point or wavelength, with one example being deviation by MacAdam Ellipses on a CIE chromaticity space. These ellipses are generally known in the art and are defined to establish the boundaries of how far colors of light can deviate from the target before a difference in the target light is perceived. MacAdam Ellipses are described as having “steps” or “standard deviations”. For example, any point on the boundary of a “1-step” ellipse drawn around the target represents one standard deviation from the target. Specified tolerances for conventional lamps (incandescent or fluorescent) are within a 4-step MacAdam Ellipse. For LEDs to become more generally accepted by consumers for general lighting applications, they should be provided with emission characteristics within accepted specified tolerances, such as the 4-step MacAdam Ellipse.

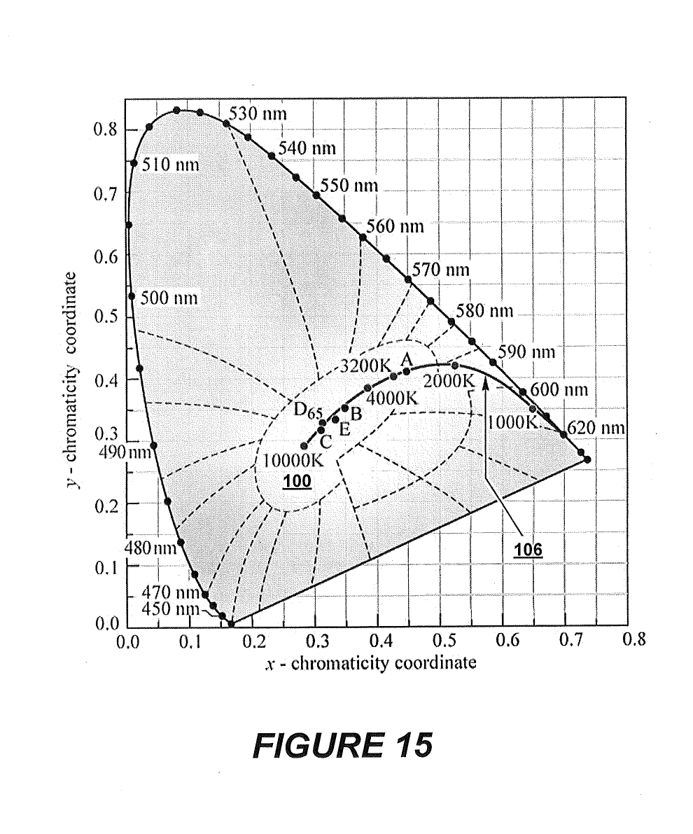

White light may be considered as light within a region around a black body locus in a two dimensional color space, such as the 1931 CIE Chromaticity Diagram illustrated in FIG. 15, having a color temperature between about 2000K and about 10000K. For example, light falling within a region defined by a 4-step, 7-step or 10-step MacAdam ellipse around a point on the planckian locus having a color temperature between about 2000K and 10000K may be considered “white.” As shown in FIG. 15, the planckian (or black body) locus 106 runs through a central region 100 of the chromaticity diagram corresponding to white light. As is understood in the art, white light having a reddish tint is considered “warm,” while light having a bluish tint is considered “cool”, even though “cool” white light has a higher color temperature than “warm” white light.

The number of lumens that can be generated from a given wafer is a function of the number of devices on the wafer, the number of lumens that can be obtained from a particular device, and the device yield, or fraction of usable devices, on the wafer. Increasing any of these quantities increases the total number of lumens that can be obtained per wafer. Increasing device yield requires a manufacturer to increase the quality and uniformity of the materials used in the manufacture of the devices, as well as the accuracy and repeatability of manufacturing methods. Increasing the wafer size to accommodate more devices per wafer, and increasing the internal quantum efficiency of devices and improving the light extraction from devices also leads to increased lumens per wafer.

In the case of white light emitting devices, the epitaxial layers generally include Group III-nitride layers, such as GaN, InGaN, InAlGaN, etc. Previously, higher quality Group III nitride structures were available only on two inch and three inch wafers of suitable substrate material, such as silicon carbide or sapphire. Two to three inch wafers are relatively small compared to wafer sizes obtainable in other material systems, such as silicon. Additionally, because the edge of every wafer, regardless of size, typically requires about an 8 mm loss, edge losses are proportionally high for smaller wafers.

Recently, 100 mm silicon carbide wafers have been developed. Because 100 mm is a common wafer size for other materials (e.g., gallium arsenide), 100 mm wafers with Group III nitride epilayers can be handled by much existing equipment, thus avoiding re-tooling. Moreover, processing costs are typically similar regardless of the size of a wafer, so that smaller wafers increase manufacturing costs per device of a given size.

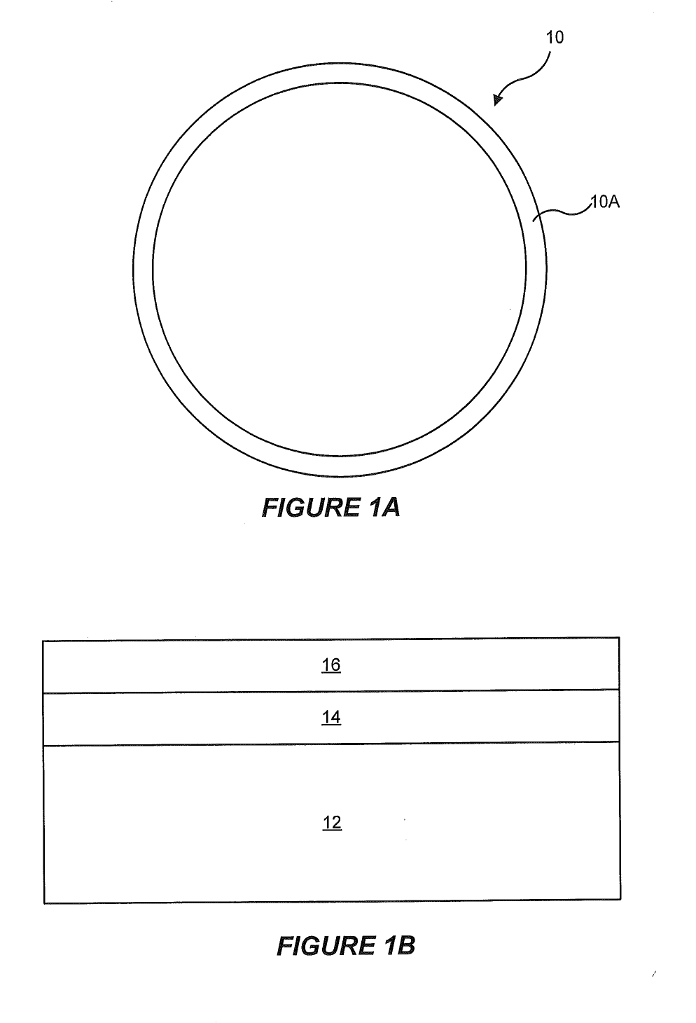

FIGS. 1A and 1B are top and side views, respectively, of an epitaxial wafer (epiwafer) 10 that is a precursor of an article of manufacture according to some embodiments. The epiwafer 10 includes a substrate 12, an n-type epitaxial region 14 and a p-type epitaxial region 14. The substrate 12 may be at least 100 millimeters in diameter. In some embodiments, the silicon carbide single crystal substrate has a polytype selected from the 3C, 4H, 6H, and 15R polytypes of silicon carbide. In particular embodiments, the substrate 12 is single crystalline n-type silicon carbide of the 4H or 6H polytype. In other embodiments, the substrate 12 may include sapphire, bulk gallium nitride (GaN), aluminum nitride (AlN), gallium nitride (GaN), silicon (Si), lithium aluminate, zinc oxide (ZnO), glass, diamond, gallium arsenide, or any other suitable substrate.

The n-type and p-type epitaxial regions 14, 16 include a light emitting active region in conjunction with a p-n junction. A detailed description of the structure of the n-type and p-type epitaxial regions 14, 16 in accordance with some embodiments is provided below.

It will be understood by those of skill in this art that the evaluation of wafers, and of epilayers on wafers, typically excludes a small edge exclusion portion 10A that will be free of fabricated semiconductor devices. The size of the edge exclusion portion 10A depends upon the measurement technique, but for a 100 mm wafer (of any material) will typically total about 5-10 mm (e.g., a perimeter portion about 2.5-5 mm wide). Thus, the measurements set forth herein take edge exclusion into account and describe the wafers and epilayers other than at their respective edge exclusion portions.

The performance of semiconductor devices, such as semiconductor light emitting devices, relates to the materials from which they are formed and the design and quality of particular layers or substrates of those materials. A lack of quality or uniformity in the materials, or in material structures that form devices or device precursors, reduces the yield and limits the sizes of resulting devices that are potentially available from the material systems.

Epitaxial growth normally produces variations in materials (composition and characteristics) across a wafer. These can include differences in concentration of one or more elements (e.g., aluminum in aluminum gallium nitride) and different thicknesses. With respect to optoelectronic devices such as LEDs, devices built from non-uniform material may show greater variation in peak wavelength, dominant wavelength, emission intensity, leakage current and/or forward voltages. Having a high variation in these parameters can reduce the yield of usable optoelectronic devices on the wafer 12. Accordingly, in order to increase the yield of usable optoelectronic devices on the wafer 12, it is desirable to form the epiwafer 10 to have as low a variation in optoelectronic properties, such as peak wavelength, dominant wavelength, emission intensity, leakage current and forward voltage, as possible.

A precursor structure 10 according to some embodiments may be extremely uniform in its physical, chemical, and electronic and optoelectronic characteristics.

Uniformity of epitaxial growth on large wafers may be obtained by performing epitaxial growth by metal-organic chemical vapor deposition (MOCVD) using an epitaxial growth system that uses a rotating susceptor design, such as the susceptor design shown in U.S. Application No. 2006/0269390, published Nov. 30, 2006, entitled Susceptor for MOCVD Reactor, the disclosure of which is incorporated herein by reference as if set forth in its entirety.

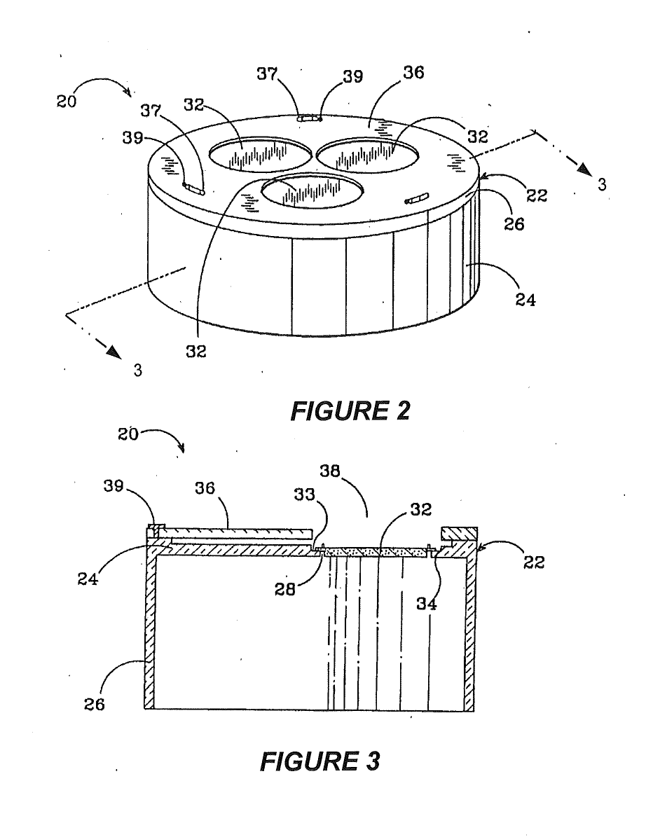

In particular, FIGS. 2 through 4 show a susceptor 20 that can hold substrates or wafers for growth of highly uniform epitaxial layers in an MOCVD reactor. The susceptor 20 can be mounted over the MOCVD reactor's heating element at the bottom of the reactor and can spin during the growth process.

The susceptor 20 includes a base structure 22 made of a base plate 24 and a cylindrical sleeve 26, which can be separate or manufactured as one structure. The base plate 24 has circular through holes 28 equally spaced around the susceptor's longitudinal axis 30. The number of through holes 28 can vary depending on the number of wafers that the susceptor 20 is designed to hold during growth.

The base structure 22 may be made of a rigid material that has a low thermal conductivity at high temperature so that it transmits less heat from the MOCVD reactor's heating element. It may also be made of a material that is reflective so that it reflects the heating element's radiative heat to further reduce the amount of heat it transmits. It may also have a low thermal expansion, so that its expansion matches that of the other susceptor components.

The base structure 22 can be made of many different materials, such as boron nitride, fused quartz, aluminum nitride, and/or a ceramic, with the aluminum nitride and ceramic embodiments being coated with a material to reduce their reactance with the source gases. In particular, the base structure 22 may be made of boron nitride or fused quartz covered by boron nitride. These materials have high thermal conductivity at low temperature, low thermal conductivity at high temperature, and boron nitride is white, which enhances the structure's reflectivity. The base structure 22 can be manufactured using known methods.

The base structure 22 can have many different dimensions. A suitable height for the cylindrical sleeve is approximately 2 inches and a suitable diameter is approximately 12 inches for a susceptor holding three 100 mm wafers. The base plate 24 also has a suitable diameter of approximately 12 inches, with the plate holes 28 equally spaced around the center of the base plate 24. A suitable diameter for the plate holes 28 is approximately 4.3 inches. The base plate 24 and the sleeve 26 can have many different thicknesses, with a suitable thickness being approximately 0.2 inches.

The susceptor 20 also includes heat transfer plugs 32, each of which fit within a respective plate hole 28. Semiconductor wafers are placed in contact with the plugs 32 during growth of the epitaxial layers and heat from the heating element should be efficiently conducted through the plugs 32 to the wafers. The plugs 32 are preferably made of a material having high thermal conductivity at high temperature and a dark color, both of which promote heat conduction. The preferred material for the plugs 32 is graphite or silicon carbide coated graphite. Each of the plugs 32 has an axial lip 33 around its outer surface, which rests on one of the axial ledges 34 on the inside surfaces of the through holes 28, such that a respective plug 32 rests within one of the holes 28.

A faceplate 36 can also be included that has holes 38 that align with the base structure's plate holes 28. The faceplate is arranged on the base structure's base plate 24 with the faceplate and base structure holes 38, 28 aligned. Only the plugs 32 are uncovered by the faceplate holes 38 and when a wafer is placed over the plug 32, only the wafer is uncovered by the holes 38.

The faceplate 36 should have approximately the same diameter as the base plate 22 and its holes 38 should have the same or slightly smaller diameter as the plate holes 28. The faceplate 36 can have many different thicknesses with a suitable thickness being approximately 0.16 inches.

The susceptor 20 is designed to spin over the reactor's heating element during growth, so the face plate 36 should be mounted to the base structure 22. Different mounting methods can be used including, but not limited to, pins on the structure 22 mated with mounting holes, and axial slots or J-slots in the faceplate 36. Alternatively, rotatable hooks can be included on the structure to mate with slots in the faceplate 36. In one embodiment, the hooks can be turned away from the center of the base plate 24 and the faceplate 36 is then placed over the base plate 24, with the stem of the hooks aligned with a respective slot. The hooks are then rotated so they are directed toward the center of the base plate 24. In the embodiment shown in FIGS. 2 through 4, the faceplate has axial slots 37 that mate with pins 39 on the structure 22. Each pin 39 has a head that passes through the widest section of one of the slots 37. The faceplate is then turned until the stem of each pin 39 is housed within the narrow section of its respective slot 37.

A space can be included between the faceplate 36 and the base structure 22 to limit the conducted heat due to contact between the faceplate 36 and the base plate 24. This is best accomplished by including a raised section on the surface of the base plate 24, around its edge.

The susceptor 20 can be used in MOCVD reactors where the susceptor is arranged at the bottom of the reactor with the circular plate facing up. Growth gases enter the reactor from the top or sides and are deposited on the uncovered wafers that are held over the plugs 40.

This susceptor 20 promotes the uniform transfer of heat from the reactor's heating element through the plugs 32, which can increase the uniformity of the epitaxial layers. The fabrication process may require less growth gas because most of the gases are deposited on the wafer. The resulting semiconductor device may have sharper interfaces and lower levels of unwanted impurities. This can increase the yield and reproducibility of the epitaxial growth process.

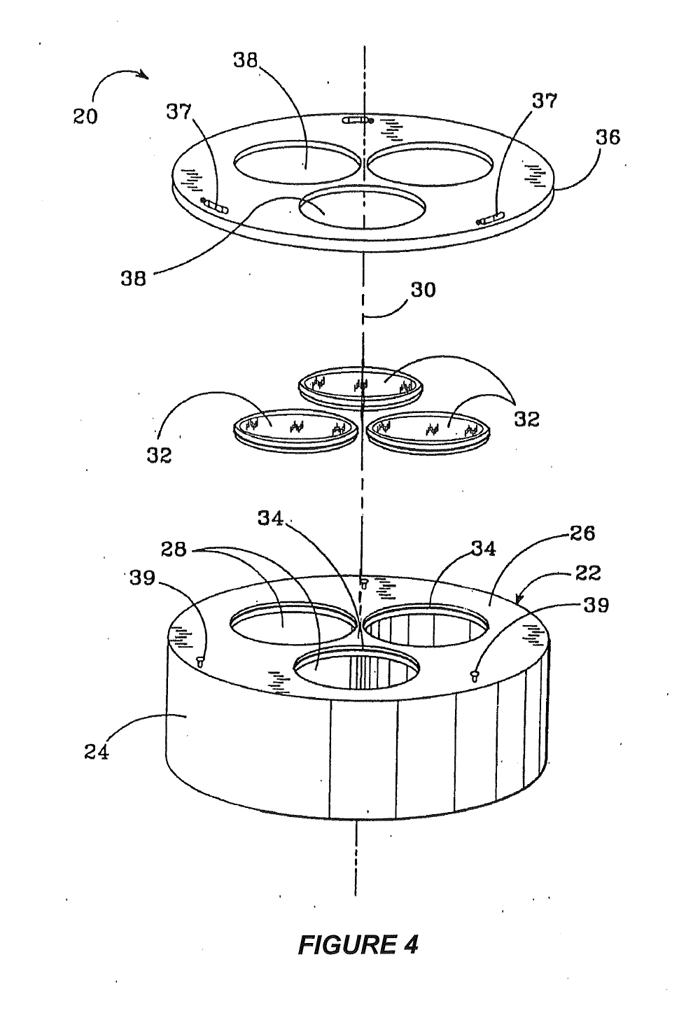

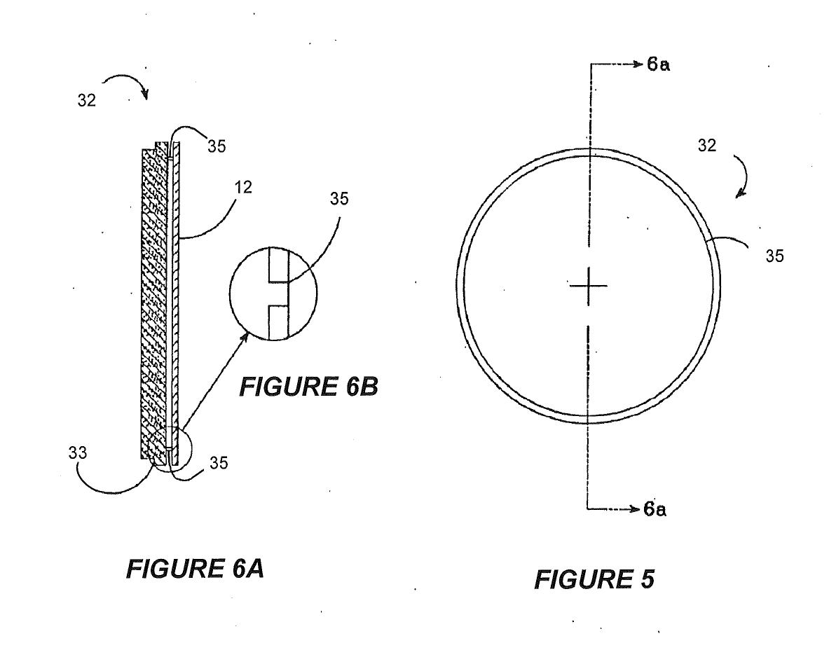

FIGS. 5, 6a and 6b show one embodiment of a heat transfer plug 32, according to the present invention. Each plug 32 is substantially puck shaped and is designed to transfer heat from the reactor's heating element to a semiconductor wafer 12 (shown in FIGS. 6a and 6b) held in contact with the plug 32. The plug 32 can have a circular ridge 35 on its surface adjacent to the wafer 12, with only the ridge 35 contacting the wafer. The circular ridge 35 may or may not be continuous around the periphery of the plug 32. Alternatively, the plug 32 may include one or more posts that extend from the plug 32, and the wafer 12 may rest on the posts while being spaced apart from the surface of the plug 32. This provides a small space between the wafer 12 and the plug 32 to promote even convective heating of the wafer. To further promote even heating of the wafer 12, the surface of the plug 32 adjacent to the wafer 12 can also have a convex, concave, or other shaped surface. The plug 32 should have a diameter that allows it to fit within one of the base plate through holes 28 and should have a size which allows for thermal expansion of the plug or base plate, with a suitable diameter being approximately 4.1 inches. Each plug 32 has a lip 33 (shown as reference number 33 in FIGS. 3 and 4) around its edge so that the plug's top section of has a slightly larger diameter than its lower section. As described above, each plug's lip 33 rests on a respective hole ledge 34.

The plug can have many different thicknesses, with a suitable thickness being approximately 0.33 inches. The ridge 35 can be many different sizes, with a suitable size being 0.002 inches high and 0.003 inches wide.

Prior to growth of the epitaxial layers, the wafers 12 and transfer plugs 32 are placed in the through holes 28 and the faceplate 36 is mounted to base structure 22 with the faceplate holes 38 aligned with the base structure's holes 28. The wafers 12 are uncovered by the faceplate 36 and when the plugs 32 are heated by the MOCVD's heating element, the wafers 12 are also heated. Growth gases are fed into the reactor as the susceptor assembly 20 spins and uniform epitaxial layers are grown on the wafers 12.

Other reactor designs that promote uniformity are so-called planetary reactor designs, such as those illustrated in expired U.S. Pat. No. 4,860,687 issued Aug. 29, 1989, entitled Device Comprising A Flat Susceptor Rotating Parallel To A Reference Surface About A Shift Perpendicular To This Surface, and expired U.S. Pat. No. 4,961,399, issued Oct. 9, 1990 entitled Epitaxial Growth Reactor Provided With A Planetary Support, the disclosures of which are incorporated herein by reference as if set forth in their entirety. In a planetary reactor, a plurality of wafers are suspended on circular wafer carriers arranged in wafer pockets disposed at angular offsets on a susceptor plate. As process gases are supplied to the reactor, the susceptor plate rotates around a central axis, while the wafer carriers rotate around their own individual axes. This dual rotation of the wafers during epitaxial growth may even out variations in temperature, pressure and/or process gas uniformity within the reactor, which may promote more uniform epitaxial growth.

A number of background aspects of the growth of Group III nitride layers on silicon carbide substrates are generally well understood in the art and can be practiced by those of ordinary skill in this art without undue experimentation. As a specific discussion, however, the structures described herein may be grown using metal organic chemical vapor deposition (MOCVD) on silicon carbide substrates. A discussion of the growth of related materials on sapphire substrates is set forth in Keller, Effect of growth termination conditions on the performance of AlGaN/GaN high electron mobility transistors, APPLIED PHYSICS LETTERS, Vol. 78, No. 20, May 14, 2001, pp 3088-90. The high uniformity obtained in the invention is also possible using related techniques such as metal-organic vapor phase epitaxy (MOVPE) or molecular beam epitaxy (MBE), although material produced by MOCVD generally costs less than material produced by MBE and MOCVD tends to produce a higher quality Group III-Nitride material (for example lower dislocation density).

In epitaxial growth of structures according to some embodiments, trimethyl gallium ((CH₃)₃Ga; “TMG”), trimethyl indium ((CH₃)₃In; “TMI”), and trimethyl aluminum ((CH₃)₃A1; “TMA”) may be used as the Group III precursors and ammonia (NH₃) may be used as the nitrogen precursor. In particular embodiments, the MN and AlGaN layers may grown in an atmosphere containing minimal (about 5 percent or less) hydrogen (H₂), such as an atmosphere that is predominantly nitrogen (N₂).

N-type doping is obtained by flowing silane (SiH₄) with the process gases, while P-type doping is obtained using bis-cyclopentadienl magnesium (Cp₂Mg) gas.

As another factor addressed by the present invention, epitaxial layers can cause bow or warp or both in substrates resulting from the stress present in the deposited films, or in some cases the stress present in the substrates. The terms bow and warp are used herein in a manner that is well understood in this art and for which appropriate definitions are available from established sources (e.g., SEMI; www.semi.org). Bow or warp are generally undesirable when processing wafers as either may be sufficient to preclude later flattening by appropriate tools such as steppers. Additionally, warp and bow can prevent uniform contact with hot surfaces during annealing or baking steps. As another problem, wafer breakage and loss can occur because vacuum tools may tend to drop wafers that are bowed or warped. As another problem, wafers may be thinned for further processing. In such thinning steps, wafer shape problems become even more severe. Thus, low strain epitaxial layers and resulting flat wafers are highly desirable.

The fabrication of Group III nitride (also referred to as “III-V”) epitaxial layers may be controlled to control the strain in the layer and help minimize or eliminate bow and warp. For example, the III-V ratio and/or the pressure under which a III-V epitaxial layer is fabricated may be controlled to control the strain in the III-V epitaxial layer. By increasing the V/III ratio, the III-V layer may be made more compressive. Furthermore, by fabricating the III-V epitaxial layer at lower pressures the III-V epitaxial layer may be more compressive. Additionally, as the thickness of the III-V epitaxial layer increases, an otherwise compressive strained layer may become tensile strained. Such tensile strain may result in defects, such as cracking, of the III-V epitaxial layer. Accordingly, the thickness, growth conditions and source materials may be controlled to avoid changes in the strain of the III-V epitaxial layer during fabrication.

Control of a GaN/AlN nucleation conditions to control the initial strain through island growth and coalescence may also be used to control the strain of a GaN epitaxial layer. For example, the pressure and NH₃ flow rates may be adjusted to reduce and/or control strain and bow resulting from the growth of a GaN epitaxial layer.

Other techniques for stress control are set forth in commonly assigned U.S. Pat. No. 6,841,001, the disclosure of which is incorporated entirely herein by reference.

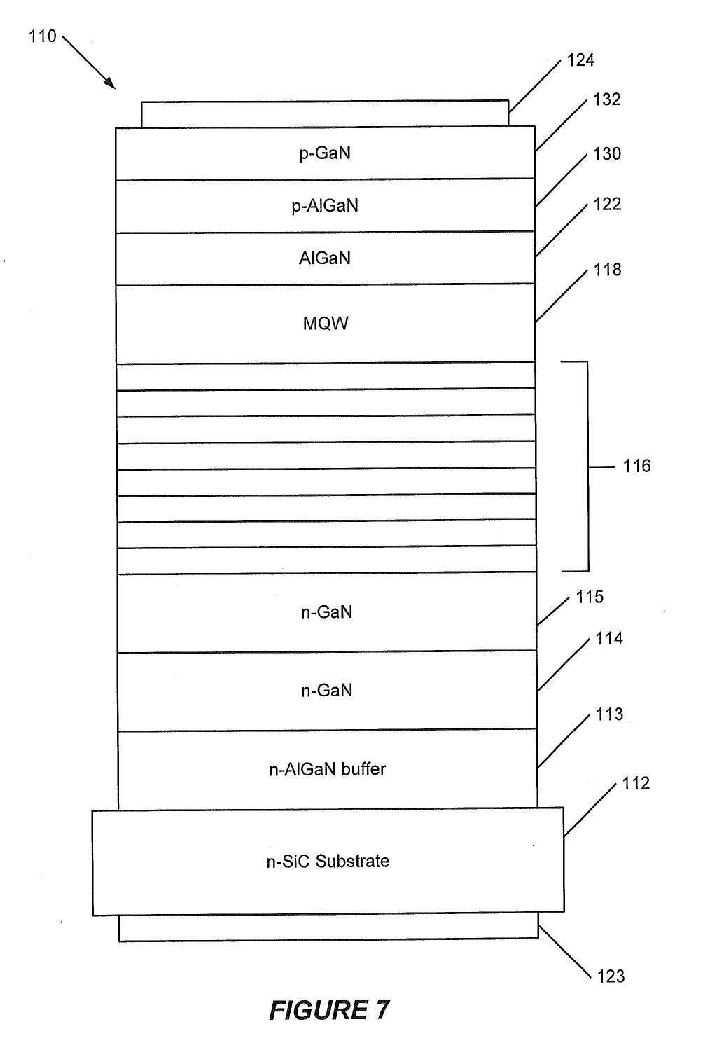

Epitaxial structures included in epiwafers in accordance with the present invention will be described with reference to FIG. 7 that illustrates a light emitting diode (LED) epitaxial structure 110. The LED structure 110 of FIG. 7 includes a substrate 112, which may be 4H or 6H n-type silicon carbide. Substrate 112 may also comprise sapphire, bulk gallium nitride (GaN), aluminum nitride (AlN), gallium nitride (GaN), silicon (Si), lithium aluminate, zinc oxide (ZnO), glass, diamond, gallium arsenide, or any other suitable substrate. Also included in the LED structure 110 of FIG. 7 is a layered semiconductor structure comprising gallium nitride-based semiconductor layers on substrate 112. Namely, the LED structure 110 illustrated includes the following layers: a conductive buffer layer 113, a first silicon-doped GaN layer 114, a second silicon doped GaN layer 115, a superlattice 116 comprising alternating layers of silicon-doped GaN and/or InGaN, an active region 118, which may be provided by a multi-quantum well structure, an undoped GaN and/or AlGaN layer 122, an AlGaN layer 130 doped with a p-type impurity, and a GaN contact layer 132, also doped with a p-type impurity. The structure further includes an n-type ohmic contact 123 on the substrate 112 and a p-type ohmic contact 124 on the contact layer 132.

Buffer layer 113 may be n-type AlGaN. Examples of buffer layers between silicon carbide and Group III-nitride materials are provided in U.S. Pat. Nos. 5,393,993 and 5,523,589 and in U.S. Publication No. 2002/0121642 entitled Vertical Geometry InGaN Light Emitting Diode, each of which is assigned to the assignee of the present invention, the disclosures of which are incorporated by reference. Similarly, embodiments of the present invention may also include structures such as those described in U.S. Pat. No. 6,201,262 entitled Group III Nitride Photonic Devices on Silicon Carbide Substrates With Conductive Buffer Interlay Structure, the disclosure of which is incorporated herein by reference.

GaN layer 114 may be between about 500 nm and 7000 nm thick inclusive, and according to some embodiments about 4000 nm thick. GaN layer 114 may be doped with silicon at a level of about 5×1017 to 7×1018 cm−3. GaN layer 115 may be between about 10 and 500 Angstroms thick inclusive, and according to some embodiments about 80 Angstroms thick. GaN layer 115 may be doped with silicon at a level of less than about 5×1019 cm−3.

As illustrated in FIG. 7, a superlattice 116 according to embodiments of the present invention includes alternating layers of InXGa1-XN and InYGa1-YN, wherein X is between 0 and 1 inclusive and X is not equal to Y. For example, X=0 and the thickness of each of the alternating layers of InGaN is about 5 Angstroms to about 40 Angstroms thick inclusive, and the thickness of each of the alternating layers of GaN is about 5 Angstroms to about 100 Angstroms thick inclusive. In certain embodiments, the GaN layers are about 30 Angstroms thick and the InGaN layers are about 15 Angstroms thick. Superlattice 16 may include from about 5 to about 50 periods (where one period equals one repetition each of the InXGa1-XN and InYGa1-YN layers that comprise the superlattice). In one embodiment, superlattice 116 comprises 25 periods. In another embodiment, superlattice 116 comprises 10 periods. The number of periods, however, may be decreased by, for example, increasing the thickness of the respective layers. Thus, for example, doubling the thickness of the layers may be used with half the number of periods. Alternatively, the number and thickness of the periods may be independent of one another.

Superlattice 16 may be doped with an n-type impurity such as silicon at a level of from about 1×1017 cm−3 to about 5×1019 cm−3. Such a dopant concentration may be an actual dopant concentration or average dopant concentration of the layers of superlattice 116. If such dopant concentration is an average dopant concentration, then it may be beneficial to provide doped layers adjacent to superlattice 116 that provide the desired average dopant concentration where doping of the adjacent layers is averaged over the adjacent layers and superlattice 116. By providing superlattice 116 between substrate 112 and active region 118, a better surface may be provided on which to grow InGaN-based active region 118. While not wishing to be bound by any theory of operation, the inventors believe that strain effects in superlattice 116 provide a growth surface that is conducive to the growth of a high-quality InGaN-containing active region. Further, the superlattice is known to influence the operating voltage of the device. Appropriate choice of superlattice thickness and composition parameters can reduce operating voltage and increase optical efficiency.

Superlattice 116 may be grown in an atmosphere of nitrogen or other gas, which enables growth of higher-quality InGaN layers in the structure. By growing a silicon-doped InGaN/GaN superlattice on a silicon-doped GaN layer in a nitrogen atmosphere, a structure having improved crystallinity and conductivity with optimized strain may be realized.

In some embodiments of the present invention, the active region 118 may comprise a single or multi-quantum well structure as well as single or double heterojunction active regions. In some embodiments of the present invention, the active region 118 comprises a multi-quantum well structure that includes multiple InGaN quantum well layers separated by barrier layers (not shown in FIG. 7).

Layer 122 is provided on active region 118 and may be undoped GaN or AlGaN between about 0 and 250 Angstroms thick inclusive. As used herein, an undoped layer/region refers to a not intentionally doped layer/region. Layer 122 may be about 35 Angstroms thick. If layer 122 comprises AlGaN, the aluminum percentage in such layer may be about 10 percent to about 30 percent, and according to some embodiments, the aluminum percentage may be about 24 percent. The level of aluminum in layer 122 may also be graded in a stepwise or continuously decreasing fashion. Layer 122 may be grown at a higher temperature than the growth temperatures in quantum well region 118 in order to improve the crystal quality of layer 122. Additional layers of undoped GaN or AlGaN may be included in the vicinity of layer 122. For example, the LED 110 may include an additional layer of undoped AlGaN about 6 Angstroms to about 9 Angstroms thick between the active region 118 and the layer 122.

An AlGaN layer 130 doped with a p-type impurity such as magnesium is provided on layer 122. The AlGaN layer 130 may be between about 0 and 300 Angstroms thick inclusive, and according to some embodiments, the AlGaN layer 130 may be about 150 Angstroms thick. A contact layer 132 of p-type GaN is provided on the layer 130 and may be about 1800 Angstroms thick. Ohmic contacts 124 and 125 are provided on the p-GaN contact layer 32 and the substrate 112, respectively.

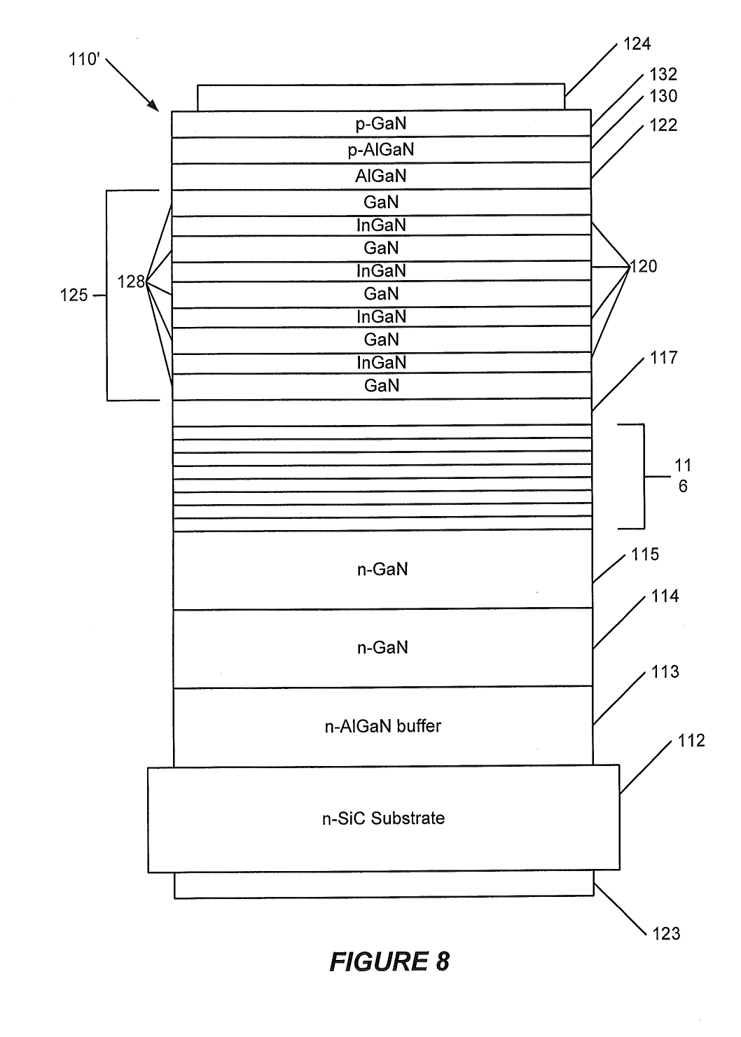

FIG. 8 illustrates further embodiments of the present invention incorporating a multi-quantum well active region. Embodiments of the present invention illustrated in FIG. 8 include a layered semiconductor structure 110′ comprising gallium nitride-based semiconductor layers grown on a substrate 112. The structure 110′ shown in FIG. 8 is similar to the structure 110 shown in FIG. 7; a description of like elements is omitted for brevity.

The structure shown in FIG. 8 includes an active region 125 that comprises a multi-quantum well structure including multiple InGaN quantum well layers 120 separated by barrier layers 128. The barrier layers 128 comprise InXGa1-XN where 0≦X<1. An indium composition of the barrier layers 128 may be less than that of the quantum well layers 120, so that the barrier layers 128 have a higher bandgap than quantum well layers 120. The barrier layers 128 and quantum well layers 120 may be undoped (i.e. not intentionally doped with an impurity atom such as silicon or magnesium). However, it may be desirable to dope the barrier layers 128 with Si at a level of less than 5×1019 cm−3, for example, if ultraviolet emission is desired.

In further embodiments of the present invention, the barrier layers 128 comprise AlXInYGa1-X-YN where 0<X<1, 0≦Y<1 and X+Y≦1. By including aluminum in the crystal of the barrier layers 128, the barrier layers 128 may be lattice-matched to the quantum well layers 120, thereby providing improved crystalline quality in the quantum well layers 120, which may increase the luminescent efficiency of the device.

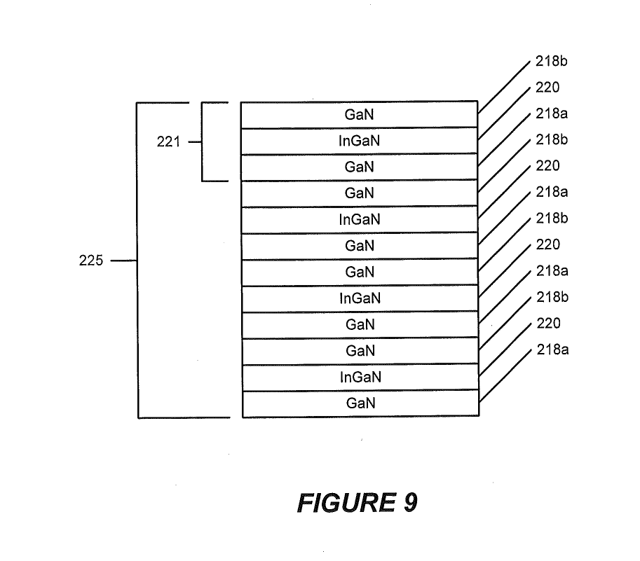

Referring to FIG. 9, embodiments of the present invention that provide a multi-quantum well structure of a gallium nitride based device are illustrated. The multi-quantum well structure illustrated in FIG. 9 may provide the active region of the LEDs illustrated in FIG. 7 and/or FIG. 8. As seen in FIG. 9, an active region 225 comprises a periodically repeating structure 221 comprising a well support layer 218a having high crystal quality, a quantum well layer 220 and a cap layer 218b that serves as a protective cap layer for the quantum well layer 220. When the structure 221 is grown, the cap layer 218b and the well support layer 218a together form the barrier layer between adjacent quantum wells 220. The high quality well support layer 218a may be grown at a higher temperature than that used to grow the InGaN quantum well layer 220. In some embodiments of the present invention, the well support layer 218a is grown at a slower growth rate than the cap layer 218b. In other embodiments, lower growth rates may be used during the lower temperature growth process and higher growth rates used during the higher temperature growth process. For example, in order to achieve a high quality surface for growing the InGaN quantum well layer 220, the well support layer 218a may be grown at a growth temperature of between about 700 and 900° C. Then, the temperature of the growth chamber is lowered by from about 0 to about 200° C. to permit growth of the high-quality InGaN quantum well layer 220. Then, while the temperature is kept at the lower InGaN growth temperature, the cap layer 218b is grown. In that manner, a multi-quantum well region comprising high quality InGaN layers may be fabricated.

For example, to provide a high quality surface for growing InGaN quantum well 220, well support layer 218a may be grown at a growth temperature in the range of about 750 degrees C. to about 900 degrees C. Then the temperature of the growth chamber may be lowered by about 50 degrees C. to permit growth of a high-quality InGaN quantum well layer 220. Then, while the temperature is kept at the lower InGaN growth temperature, the cap layer 218b is grown.

Active regions 125 and 225 of FIGS. 8 and 9 may be grown in a nitrogen atmosphere, which may provide increased InGaN crystal quality. Barrier layers 118, the well support layers 218a and/or the cap layers 218b may be between about 50 Angstroms and 400 Angstroms thick inclusive. The combined thickness of corresponding ones of the well support layers 218a and the cap layers 218b may be from about 50 Angstroms to about 400 Angstroms thick inclusive. The barrier layers 118, the well support layers 218a, and/or the cap layers 218b may be greater than about 75 Angstroms thick, and according to some embodiments, greater than about 100 Angstroms thick, greater than about 150 Angstroms thick, or even greater than about 200 Angstroms thick. Also, that the well support layers 218a may be thicker than the cap layers 218b. Thus, the cap layers 218b may be as thin as possible while still reducing the desorption of indium from or the degradation of the quantum well layers 220. The quantum well layers 120 and 220 may be between about 10 Angstroms and about 50 Angstroms thick inclusive. The quantum well layers 120 and 220 may be greater than 20 Angstroms thick, and according to some embodiments, quantum well layers 120 and 220 may be about 25 Angstroms thick. The thickness and percentage of indium in the quantum well layers 120 and 220 may be varied to produce light having a desired wavelength. Typically, the percentage of indium in quantum well layers 120 and 220 is about 25 percent to about 30 percent, however, depending on the desired wavelength, the percentage of indium has been varied from about 5 percent to about 50 percent.

In some embodiments of the present invention, the bandgap of superlattice 116 exceeds the bandgap of the quantum well layers 120. This may be achieved by adjusting the average percentage of indium in superlattice 116. The thickness (or period) of the superlattice layers and the average indium percentage of the layers may be chosen such that the bandgap of superlattice 116 is greater than the bandgap of the quantum wells 120. By keeping the bandgap of superlattice 116 higher than the bandgap of the quantum wells 120, unwanted absorption in the device may be reduced and luminescent emission may be increased. The bandgap of superlattice 116 may be from about 2.95 eV to about 3.35 eV. In some embodiments, the bandgap of superlattice 116 is about 3.15 eV.

In additional embodiments of the present invention, the LED structure illustrated in FIG. 8 includes a spacer layer 117 disposed between superlattice 116 and the active region 125. The spacer layer 117 may comprise undoped GaN. The presence of the optional spacer layer 117 between the doped superlattice 116 and active region 125 may deter silicon impurities from becoming incorporated into the active region 125. This, in turn, may improve the material quality of the active region 125 that provides more consistent device performance and better uniformity. Similarly, a spacer layer may also be provided in the LED structure illustrated in FIG. 7 between superlattice 116 and the active region 118.

Returning to FIG. 8, the layer 122 may be provided on the active region 125 and layer 122 may be undoped GaN or AlGaN between about 0 and 250 Angstroms thick inclusive. According to some embodiments, the layer 122 may be about 35 Angstroms thick. If the layer 122 comprises AlGaN, the aluminum percentage in such layer may be about 10 percent to about 30 percent, and according to some embodiments, the aluminum percentage may be about 24 percent. The level of aluminum in the layer 122 may also be graded in a stepwise or continuously decreasing fashion. The layer 122 may be grown at a higher temperature than the growth temperatures in the active region 125 in order to improve the crystal quality of the layer 122. Additional layers of undoped GaN or AlGaN may be included in the vicinity of layer 122. For example, the LED illustrated in FIG. 8 may include an additional layer of undoped AlGaN about 6 Angstroms to about 9 Angstroms thick between the active regions 125 and the layer 122.

An AlGaN layer 30 doped with a p-type impurity such as magnesium is provided on layer 122. The AlGaN layer 30 may be between about 0 and 300 Angstroms thick inclusive, and according to some embodiments, AlGaN layer 30 may be about 150 Angstroms thick. A contact layer 32 of p-type GaN is provided on the layer 30 and may be about 1800 Angstroms thick. Ohmic contacts 24 and 25 are provided on the p-GaN contact layer 32 and the substrate 112, respectively. Ohmic contacts 24 and 25 are provided on the p-GaN contact layer 32 and the substrate 112, respectively.

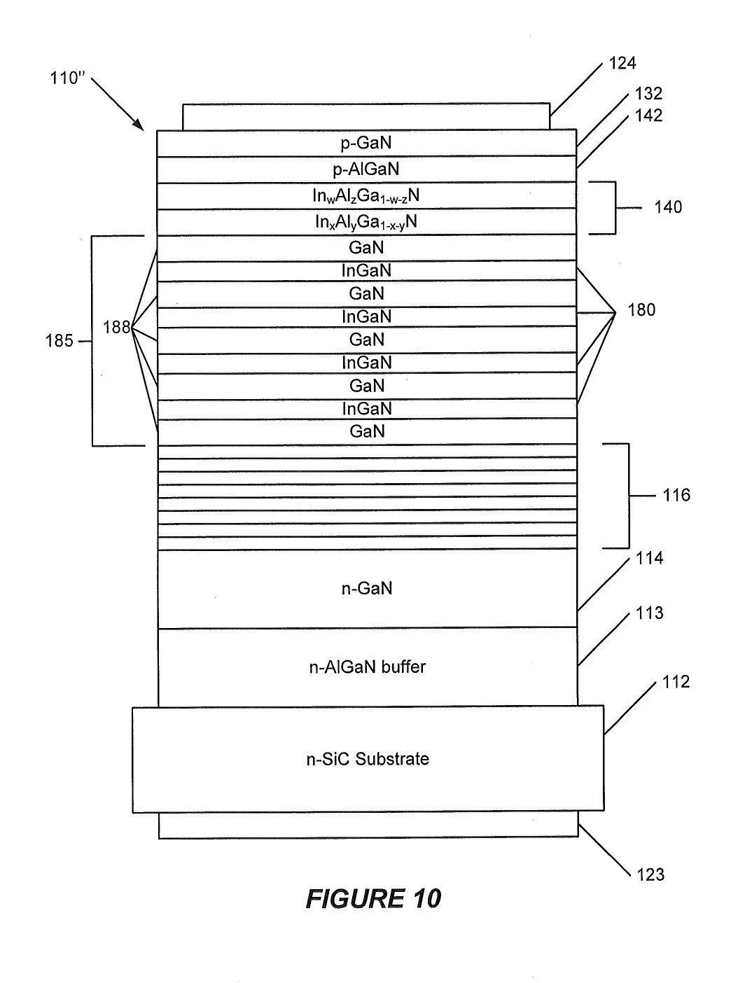

FIG. 10 illustrates further embodiments of the present invention incorporating a Group III-nitride layer incorporating indium on the active region of the device. For example, an InAlGaN cap structure may be provided. Embodiments of the present invention illustrated in FIG. 10 include a layered semiconductor structure 110″ comprising gallium nitride-based semiconductor layers grown on a substrate 112. The structure 110″ shown in FIG. 10 is similar to the structure 110 shown in FIG. 7; a description of like elements is omitted for brevity.

In the device 110″ of FIG. 10, the active region 185 may include a multi-quantum well structure that includes multiple InGaN quantum well layers 180 separated by barrier layers 188. The barrier layers 188 comprise InXGa1-XN where 0≦X<1. The indium composition of the barrier layers 188 may be less than that of the quantum well layers 180, so that the barrier layers 188 have a higher bandgap than quantum well layers 180. The barrier layers 188 and quantum well layers 180 may be undoped (i.e. not intentionally doped with an impurity atom such as silicon or magnesium). However, it may be desirable to dope the barrier layers 188 with Si at a level of less than 5×1019 cm−3, for example, if ultraviolet emission is desired.

In further embodiments of the present invention, the barrier layers 188 comprise AlXInYGa1-X-YN where 0<X<1, 0≦Y<1 and X+Y≦1. By including aluminum in the crystal of the barrier layers 188, the barrier layers 188 may be lattice-matched to the quantum well layers 180, thereby allowing improved crystalline quality in the quantum well layers 180, which can increase the luminescent efficiency of the device.

The active region 185 may also be provided as illustrated in FIG. 9 and described above with reference to FIGS. 7 through 9. In some embodiments of the present invention, the active region 185 includes 3 or more quantum wells and in certain embodiments, eight (8) quantum wells are provided. The thickness of the quantum well structures may be from about 30 Angstroms to about 250 Angstroms. In some embodiments of the present invention, the thickness of a quantum well structure may be about 120 Angstroms with the thickness of the well layer being about 25 Angstroms.

The LED structure illustrated in FIG. 10 may also include a spacer layer disposed between superlattice 116 and the active region 185 as described above.

Returning to FIG. 10, a Group III-nitride capping layer 140 that includes indium may be provided on the active region 185 and, more specifically, on the quantum well 180 of the active region 185. The Group III-nitride capping layer 140 may include InAlGaN between about 10 Angstroms and 180 Angstroms thick inclusive. The capping layer 140 may be of uniform composition, multiple layers of different compositions and/or graded composition. In some embodiments of the present invention, the capping layer 140 includes a first capping layer having a composition of InxAlyGa1-x-yN, where 0<x≦0.2 and 0≦y≦0.4 and having a thickness of from about 10 Angstroms to about 200 Angstroms and a second capping layer having a composition of InwAlzGa1-w-zN, where 0<w≦0.2 and y≦z<1 and having a thickness of from about 10 Angstroms to about 120 Angstroms. In certain embodiments of the present invention, the first capping layer has a thickness of about 80 Angstroms, x=0.1 and y=0.25 and the second capping layer has a thickness of about 30 Angstroms, w=0.05 and z=0.55. The capping layer 140 may be grown at a higher temperature than the growth temperatures in the active region 185 in order to improve the crystal quality of the layer 140. Additional layers of undoped GaN or AlGaN may be included in the vicinity of layer 140. For example, a thin layer of GaN may be provided between a last quantum well layer and the capping layer 140. The capping layer 140 that includes indium may be more closely lattice matched to the quantum wells of the active region 185 and may provide a transition from the lattice structure of the active region 185 to the lattice structure of the p-type layers. Such a structure may result in increased brightness of the device.

In some embodiments of the present invention, the indium containing capping layer 140 may be provided in light emitting devices as described, for example, in United States Provisional Patent Application Serial No. 2006/0046328 entitled “Ultra-Thin Ohmic Contacts For P-Type Nitride Light Emitting Devices And Methods Of Forming”, U.S. Pat. No. 7,557,380 entitled “Light Emitting Devices Having A Reflective Bond Pad And Methods Of Fabricating Light Emitting Devices Having Reflective Bond Pads”, U.S. Pat. No. 6,664,560, United States Patent Publication No. 2006/0002442 entitled “Light Emitting Devices Having Current Blocking Structures And Methods Of Fabricating Light Emitting Devices Having Current Blocking Structures”, U.S. Patent Publication No. 2002/0123164 entitled “Light Emitting Diodes Including Substrate Modifications For Light Extraction And Manufacturing Methods Therefor” and/or in U.S. Patent Publication No. 2003/0168663 entitled “Reflective Ohmic Contacts For Silicon Carbide Including A Layer Consisting Essentially Of Nickel, Methods Of Fabricating Same, And Light Emitting Devices Including The Same,” the disclosures of which are incorporated herein as if set forth in their entirety.

While embodiments of the present invention have been described with multiple quantum wells, the benefits from the teachings of the present invention may also be achieved in single quantum well structures. Thus, for example, a light emitting diode may be provided with a single occurrence of the structure 221 of FIG. 9 as the active region of the device. Thus, while different numbers of quantum wells may be used according to embodiments of the present invention, the number of quantum wells will typically range from 1 to 10 quantum wells.

LED structures discussed above with respect to FIGS. 7-10 are also discussed in U.S. Pat. No. 6,958,497 entitled “Group III Nitride Based Light Emitting Diode Structures With A Quantum Well And Superlattice, Group III Nitride Based Quantum Well Structures And Group III Nitride Based Superlattice Structures” and U.S. Patent Publication No. 2005/0056824 entitled “Group III Nitride Based Quantum Well Light Emitting Device Structures With An indium Containing Capping Structure”, the disclosures of which are hereby incorporated herein in their entirety by reference.

According to additional embodiments of the present invention, a Group III nitride based light emitting diode 50 may include a Group III nitride semiconductor base region with modulated silicon doping as described, for example, in U.S. application Ser. No. 12/848,600, filed Aug. 2, 2010, entitled Semiconductor Device Structures with Modulated and Delta Doping and Related Methods, the disclosure of which is incorporated herein by reference in its entirety.

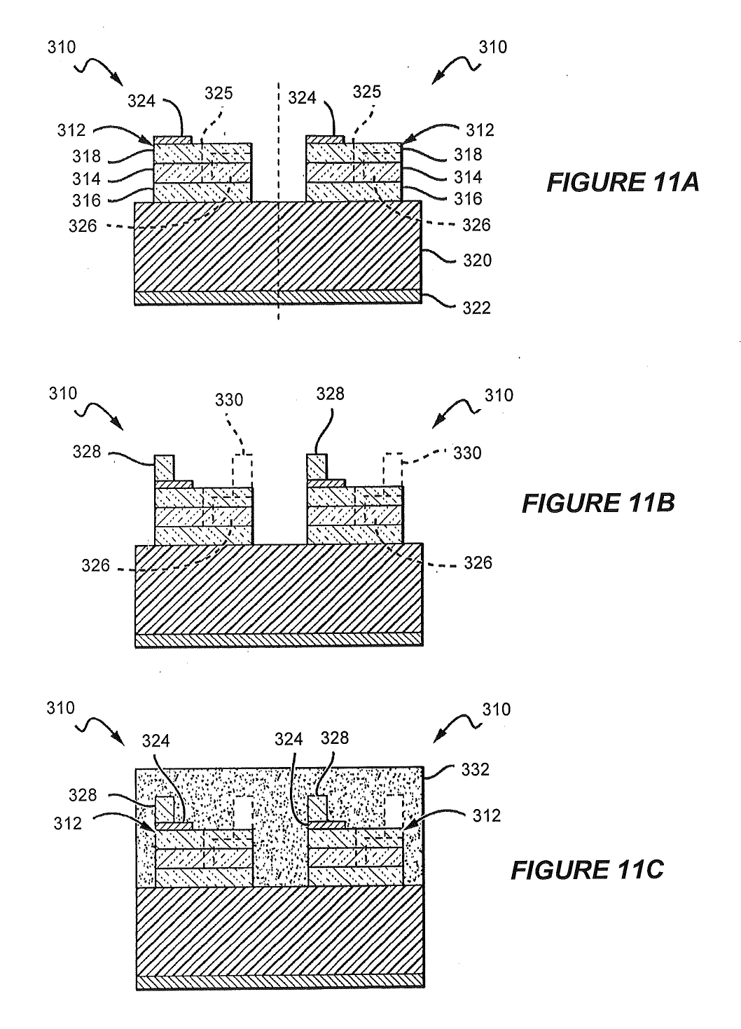

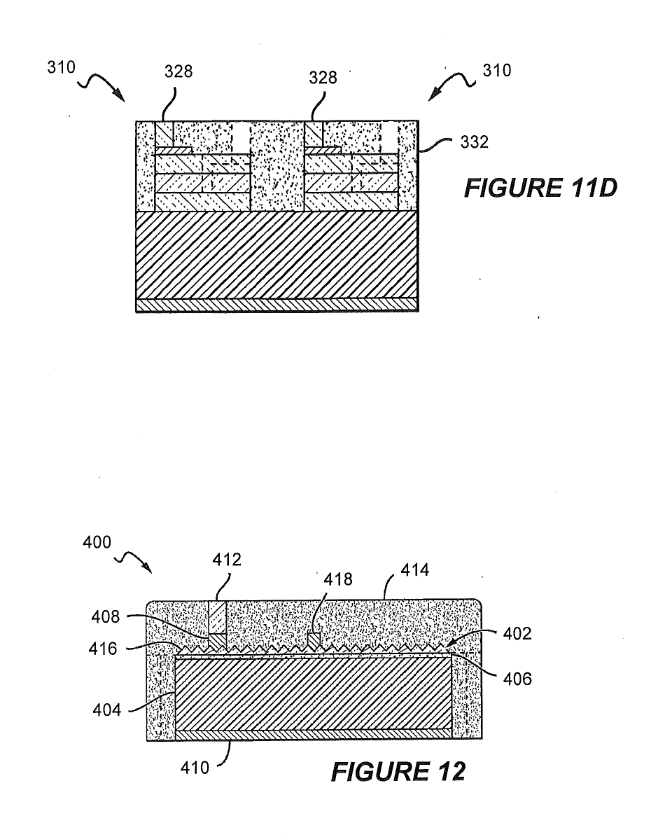

FIGS. 11A through 11D show fabricated LED wafers 10 according to some embodiments. That is, the LEDs chips 310 have not been separated/singulated from wafer into individual LED chips. Phantom lines are included to show separation or dicing line between the LED chips 310. FIGS. 11A through 11D also show only two devices at the wafer level, but it is understood that many more LED chips can be formed from a single wafer. For example, when fabricating LED chips having a 1 millimeter (mm) square size, up to 4500 LED chips can be fabricated on a 3 inch wafer. Up to 10,800 0.85×0.85 mm LED chips can be fabricated on a 100 millimeter wafer.

Each of the LED chips 310 comprises an epitaxial semiconductor structure 312 fabricated as described above. The layers of the LED epitaxial structures 312 generally comprise an active layer/region 314 sandwiched between first and second oppositely doped epitaxial layers 316, 318, all of which are formed on an epitaxial growth substrate. In this embodiment the LEDs structures 312 are shown as separate devices on a substrate 320, which may be the epitaxial growth substrate or may be a carrier substrate onto which the epitaxial layers have been wafer bonded. This separation can be achieved by having portions of the active region 314 and doped layers 316, 318 etched down to the substrate 320 to form the open areas between the LEDs 312. In other embodiments, the active layer 314 and doped layers 316, 318 can remain continuous layers on the substrate 320 and can be separated into individual devices when the LED chips are singulated.

The substrate 320 can be made of many materials such as sapphire, silicon carbide, aluminum nitride (AlN), GaN, with a suitable substrate being a 4H polytype of silicon carbide, although other silicon carbide polytypes can also be used including 3C, 6H and 15R polytypes. In embodiments where the substrate 320 is a carrier substrate, the substrate 320 can include other materials, such as silicon, alumina, copper, etc.

Each of the LEDs 312 can have first and second contacts 322, 324. In the embodiment shown, the LEDs have a vertical geometry with the first contact 322 on the substrate 320 and the second contact 324 on the p-type layer 318. The first contact 322 is shown as one layer on the substrate, but when the LED chips are singulated from the wafer the first contact 322 will also be separated such that each LED chip 10 has its own portion of the first contact 322. An electrical signal applied to the first contact 322 spreads into the n-type layer 316 and a signal applied to the second contact 324 spreads into the p-type layer 318. The first and second contacts can comprise many different materials such as Au, copper (Cu) nickel (Ni), indium (In), aluminum (Al), silver (Ag), or combinations thereof. In still other embodiments the first and second contacts can comprise conducting oxides and transparent conducting oxides such as indium tin oxide, nickel oxide, zinc oxide, cadmium tin oxide, titanium tungsten nickel, indium oxide, tin oxide, magnesium oxide, ZnGa2O4, ZnO2/Sb, Ga2O3/Sn, AgInO2/Sn, In2O3/Zn, CuAlO2, LaCuOS, CuGaO2 and SrCu2O2. The choice of material used can depend on the location of the contacts as well as the desired optical and electrical characteristics such as transparency, junction resistivity and sheet resistance.

In the case of Group-III nitride devices, it is known that a thin semitransparent current spreading layer typically can cover some or all of the p-type layer 318. It is understood that the second contact 324 can include such a layer which is typically a metal such as platinum (Pt) or a transparent conductive oxide such as indium tin oxide (ITO), although other materials can also be used. The first and second contacts 322, 324 are hereinafter referred to as the n-type and p-type contacts respectively.

The present invention can also be used with LEDs having lateral geometry wherein both contacts are on the top of the LEDs. A portion of the p-type layer 318 and active region is removed, such as by etching to expose a contact mesa on the n-type layer 316. The boundary of the removed portion of the active region 314 and p-type layer 318 is designated by vertical phantom line 325. A second lateral n-type contact 326 (also shown in phantom) is provided on the mesa of the n-type layer 316. The contacts can comprise known materials deposited using known deposition techniques.

Referring now to FIG. 11B, and according to the present invention, a p-type contact pedestal 328 is formed on the p-type contact 324 that is utilized to make electrical contact to the p-type contact 324 after coating of the LEDs 312. The pedestal 328 can be formed of many different electrically conductive materials and can be formed using many different known physical or chemical deposition processes such as electroplating, mask deposition (e-beam, sputtering), electroless plating, or stud bumping, with the preferred contact pedestal being gold (Au) and formed using stud bumping. This method is typically the easiest and most cost effective approach. The pedestal 328 can be made of other conductive materials beyond Au, such as the metals utilized for the first and second contacts including Cu, Ni, In, or combinations thereof, or the conducting oxides and transparent conducting oxides listed above.

The process of forming stud bumps is generally known and only discussed briefly herein. Stud bumps are placed on the contacts (bond pads) through a modification of the “ball bonding” process used in conventional wire bonding. In ball bonding, the tip of the bond wire is melted to form a sphere. The wire bonding tool presses this sphere against the contact, applying mechanical force, heat, and/or ultrasonic energy to create a metallic connection. The wire bonding tool next extends the gold wire to the connection pad on the board, substrate, or lead frame, and makes a “stitch” bond to that pad, and finishes by breaking off the bond wire to begin another cycle. For stud bumping, the first ball bond is made as described, but the wire is then broken close above the ball. The resulting gold ball, or “stud bump” remains on the contact and provides a permanent, reliable connection through to the underlying contact metal. The stud bumps can then be flattened (or “coined”) by mechanical pressure to provide a flatter top surface and more uniform bump heights, while at the same time pressing any remaining wire into the ball.

The height of the pedestal 328 can vary depending on the desired thickness of the phosphor loaded binder coating and should be high enough to match or extend above the top surface of the phosphor loaded binder coating from the LED. The height can exceed 200 micrometers, with typical pedestal height in the range of 20 to 60 micrometers. In some embodiments, more than one stud bump can be stacked to achieve the desired pedestal height. The stud bumps or other forms of the pedestal 328 can also have a reflecting layer or can be made of a reflective material to minimize optical losses.

For the vertical geometry type LEDs 312 shown, only one pedestal 328 is needed for the p-type contact 324. For alternative lateral geometry LEDs a second n-type pedestal 330 (shown in phantom) is formed on the lateral geometry n-type contact 326, typically of the same materials, to substantially the same height as the p-type pedestal 328, and formed using the same processes.

Referring now to FIG. 11c, the wafer is blanketed by a phosphor/binder coating 332 that covers each of the LEDs 312, and its contact 322, and has a thickness such that it covers/buries the pedestal 328. For lateral geometry devices, the contact 326 and pedestal 330 are also buried. The present invention provides the advantage of depositing the phosphor coating over the LEDs 312 at the wafer level without the need for alignment over particular devices or features. Instead, the entire wafer is covered, which provides for a simpler and more cost effective fabrication process. The phosphor/binder coating can be applied using different processes such as spin coating, dispensing, electrophoretic deposition, electrostatic deposition, printing, jet printing or screen printing. In other embodiments the coating 332 can be provided as a separately fabricated preform that can be bonded over each of the LEDs.

In some embodiments, the phosphor can be deposited over the wafer in a phosphor/binder mixture using spin coating. Spin coating is generally known in the art and generally comprises depositing the desired amount of binder and phosphor mixture at the center of the substrate and spinning the substrate at high speed. The centrifugal acceleration causes the mixture to spread to and eventually off the edge of the substrate. Final layer thickness and other properties depend on the nature of the mixture (viscosity, drying rate, percent phosphor, surface tension, etc.) and the parameters chosen for the spin process. For large wafers it may be useful to dispense the phosphor/binder mixture over the substrate before spinning the substrate at high speed.

In other embodiments, the phosphor is deposited on the wafer using known electrophoretic deposition methods. The wafer and its LEDs are exposed to a solution containing phosphor particles suspended in a liquid. An electrical signal is applied between the solution and the LEDs which creates an electrical field that causes the phosphor particles to migrate to and deposit on the LEDs. The process typically leaves the phosphor blanketed over the LEDs in powder form. A binder can then be deposited over the phosphor with the phosphor particles sinking into the binder to form the coating 332. The binder coating can be applied using many known methods and in one embodiment, the binder coating can be applied using spin coating.

The phosphor/binder coating 332 can then be cured using many different curing methods depending on different factors such as the type of binder used. Different curing methods include but are not limited to heat, ultraviolet (UV), infrared (IR) or air curing.

Different factors determine the amount of LED light that will be absorbed by the phosphor/binder coating in the final LED chips, including but not limited to the size of the phosphor particles, the percentage of phosphor loading, the type of binder material, the efficiency of the match between the type of phosphor and wavelength of emitted light, and the thickness of the phosphor/binding layer. These different factors can be controlled to control the emission wavelength of the LED chips according to the present invention.

Different materials can be used for the binder, with materials preferably being robust after curing and substantially transparent in the visible wavelength spectrum. Suitable material include silicones, epoxies, glass, inorganic glass, spin-on glass, dielectrics, BCB, polymides, polymers and hybrids thereof, with the preferred material being silicone because of its high transparency and reliability in high power LEDs. Suitable phenyl- and methyl-based silicones are commercially available from Dow® Chemical. In other embodiments, the binder material can be engineered to be index matched with the features such as the chip (semiconductor material) and growth substrate, which can reduce total internal reflection (TIR) and improve light extraction.

Many different phosphors can be used in the coating 332 according to the present invention. The present invention is particularly adapted to LED chips emitting white light. In one embodiment according to the present invention LEDs 312 emit light in the blue wavelength spectrum and the phosphor absorbs some of the blue light and re-emits yellow. The LED chips 310 emit a white light combination of blue and yellow light. In one embodiment the phosphor comprises commercially available YAG:Ce, although a full range of broad yellow spectral emission is possible using conversion particles made of phosphors based on the (Gd,Y)3(Al,Ga)5O12:Ce system, such as the Y3Al5O12:Ce (YAG). Other yellow phosphors that can be used for white emitting LED chips include: Tb3-xRExO12:Ce(TAG); RE=Y, Gd, La, Lu; or Sr2-x-yBaxCaySiO4:Eu.

First and second phosphors can also be combined for higher CRI white of different white hue (warm white) with the yellow phosphors above combined with red phosphors. Different red phosphors can be used including: SrxCal-xS:Eu, Y; Y=halide; CaSiAlN3:Eu; or Sr2-yCaySiO4:Eu

Other phosphors can be used to create saturated color emission by converting substantially all light to a particular color. For example, the following phosphors can be used to generate green saturated light: SrGa2S4:Eu; Sr2-yBaySiO4:Eu; or SrSi2O2N2:Eu.

The following lists some additional suitable phosphors used as conversion particles in an LED chips 310, although others can be used. Each exhibits excitation in the blue and/or UV emission spectrum, provides a desirable peak emission, has efficient light conversion, and has acceptable Stokes shift:

Yellow/Green

(Sr,Ca,Ba) (Al,Ga)2S4:Eu2+Ba2(Mg,Zn)Si2O7:Eu2+Gd0.46Sr0.31A11.23OxF1.38:Eu2+0.06 (Ba1-x-ySrxCay)SiO4:Eu Ba2SiO4:Eu2+

Red

Lu2O3:Eu3+(Sr2-xLax)(Ce1-xEux)O4 Sr2Ce1-xEuO4 Sr2-xEuxCeO4 SrTiO3:Pr3+,Ga3+CaAlSiN3:Eu2+Sr2Si5N8:Eu2+

Different sized phosphor particles can be used including but not limited to 10-100 nanometer(nm)-sized particles to 20-30 micrometers sized particles, or larger. Smaller particle sizes typically scatter and mix colors better than larger sized particles to provide a more uniform light. Larger particles are typically more efficient at converting light compared to smaller particles, but emit a less uniform light. In one embodiment, the particle sizes are in the range of 2-5 micrometers. In other embodiments, the coating 332 can comprise different types of phosphors or can comprise multiple phosphor coatings for monochromatic or polychromatic light sources.

The methods according to the present invention can be more effective at depositing different sized particles on an LED compared to conventional deposition processes such as EPD. In EPD deposition processes similarly sized phosphor particles may respond to the electric field in the solution and deposit on the LED. Particles having different sizes, and in particular larger sizes, may not react to the electric field in the same way and may not deposit. Utilizing the present method, different sized phosphors can be included in the coating as desired before it is applied such that the end coating can have the desired combination of smaller sizes to effectively scatter and mix the light, and larger sizes to efficiently convert the light.

The coating 332 can also have different concentrations or loading of phosphor materials in the binder, with a typical concentration being in range of 30-70% by weight. In one embodiment, the phosphor concentration is approximately 65% by weight, and is preferably uniformly dispersed throughout the binder. Still in other embodiments the coating can comprise multiple layers of different concentrations or types of phosphors, and the multiple layers can comprise different binder materials. In other embodiments one or more of the layers can be provided without phosphors with our more being substantially transparent to the LED light. As more fully described below, in some embodiments a first coat of clear silicone can be deposited followed by phosphor loaded layers.

As discussed above, the pedestal 328 (and pedestal 330 for lateral devices) are buried by the coating 332, which allows for the LED chips 10 to be coated without the need for alignment. After the initial coating of the LED chips, further processing is needed to expose the pedestal 328. Referring now the FIG. 11d, the coating 332 is thinned or planarized so that the pedestals 328 are exposed through the coating's top surface. Many different thinning processes can be used including known mechanical processes such as grinding, lapping or polishing, preferably after the binder has cured. Other fabrication methods can comprise a squeegee to thin the coating before cured or pressure planarization can also be used before the coating is cured. Still in other embodiments the coating can be thinned using physical or chemical etching, or ablation. The thinning process not only exposes the pedestals, but also allows for planarizing of the coating and for control of the final thickness of the coating over the LEDs. As mentioned above, the coating 32 can have many different thicknesses following planarization, with a range of thicknesses in one embodiment being 1 to 100 micrometers. In still another embodiment, the suitable range of thicknesses is 30 to 50 micrometers. In other embodiments, the thickness of the coating can be non-uniform across the wafer or across a single LED, such as to compensate for emission variations across the wafer.

Following planarization, the surface root mean squared roughness of the coating should be approximately 10 nm or less, although the surface can have other surface roughness measurements. In some embodiments the surface can be textured during planarization. In other embodiments, after planarization the coating or other surfaces, can be textured such as by laser texturing, mechanical shaping, etching (chemical or plasma), scratching or other processes, to enhance light extraction. Texturing results in surface features that are 0.1-5 micrometers tall or deep, and preferably 0.2-1 micrometers. In other embodiments, the surface of the LEDs 12 can also be textured or shaped for improved light extraction.

In some embodiments, one or more surfaces of the LED may be textured to enhance light extraction from the LED, which increases the total lumens output by the device. LED chips formed on wafers according to some embodiments can be arranged in different ways with many different features such as features to enhance LED chip light extraction. For example, FIG. 12 shows an LED chip structure 400 that includes texturing for enhanced light extraction. It comprises an LED 402 on a substrate 404 with the LED preferably flip-chip mounted on the substrate 404 by a bonding material 406. In other embodiments the substrate can comprise the growth substrate for the LED 402. The LED 402 can be made of many different semiconductor materials such as those described above, and can comprise the layers described above including the active layer/region and the oppositely doped layers (n-type and p-type). For ease of illustration and understanding, the different layers of the LED 402 are not shown.

The LED chip 400 further comprises first and second contacts 408, 410. For flip-chip LEDs, the first contact 408 is on the n-type layer and the second contact 410 is in the form of a layer of conductive material on the substrate 404 arranged such that an electrical signal applied to the second contact 410 spreads through the substrate 404 to the LED's p-type layer. The contacts 408, 410 can be made of any of the conductive materials described above, with the second contact 410 in this embodiment comprising AuSn. It is understood that for lateral geometry devices the first and second contacts can be included on the surfaces of the LED 402.

A pedestal 412 is included on the first contact 408 that can be made of the materials described above and can be fabricated using the methods described above. For lateral geometry devices a second pedestal can be included on the second contact. A phosphor/binder coating 414 can be included over the LED 402 with the pedestal 412 extending from the first contact 408 to the top surface of the coating 414. The coating 414 can comprise the materials described above and can be applied and planarized using the methods described above. In the embodiment shown, the surface 416 of the LED 402 is textured, roughened or patterned to enhance light extraction. The texturing can be applied using known mechanical or etching methods as well as micro-nano imprinting methods. It is also understood that the opposite surface of the LED that is adjacent to the bonding material 406 can also be textured to enhance light extraction, with the texturing performed prior to flip-chip mounting and with the texturing embedded in the bonding material 406.

For the LED chip 400, the coating 414 extends along the side surfaces of the substrate 404 which can be formed using many different methods. For LED chips formed using this method and formed with stabilization portion of the substrate remaining, a portion of the side surface will remain that is uncovered by the coating 414 corresponding to the stabilization portion. In an alternative groove and substrate thinning method according to the present invention, the grooves can be made wider such that when they are filled with the coating the wafer can be stabilized by the coating material within the grooves. The substrate can then be thinned up to the bottom of the grooves, and the LED chips separated. This can leave a coating along substantially all of the side surfaces of the LED chips, which can enhance uniform LED chip light emission.

Different embodiments of LED chips can have different dimensions for their layers and features. In the embodiment shown, the second contact 410 can be approximately 3 micrometers thick, the substrate 404 can be approximately 100 micrometers thick and the LED 402 can have an overall thickness of approximately 3 micrometers. The roughening of the LED can result in features having different depths in said LED 402, with the roughening providing valleys having a depth of approximately 2 micrometers. Although the depth of the textured features can vary, the preferred depth is greater than 10% of the overall thickness of the LED 402. The thickness of the coating 414 over the top surface of the LED 402 is approximately 30 micrometers as measured from the lowest point in the valleys. The contact 408 is approximately 5 micrometers thick as measured from the lowest point in the valleys, with the pedestal being approximately 25 micrometers tall.

Embodiments of LED chips according to the present invention can also comprise additional features to further enhance light emission uniformity and efficiency. A current spreading structure 418 can be included on the LED 402 to improve current spreading and injection from the first contact 408. The current spreading structure can have many different forms, but preferably comprises fingers of conductive material on the surface of the LED 402 contacting the first contact 414. The current spreading structure can be deposited using known methods and can comprise the materials described above for the contacts and pedestals including Au, Cu, Ni, In, Al, Ag or combinations thereof and conducting oxides and transparent conducting oxides.

Other methods of wafer-level phosphor deposition may be used, such as those shown in U.S. Publication No. 2008/0179611, published Jul. 31, 2008, entitled Wafer Level Phosphor Coating Method And Devices Fabricated Utilizing Method, U.S. Publication No. 2008/0173884, published Jul. 24, 2008, entitled Wafer Level Phosphor Coating Method And Devices Fabricated Utilizing Method, U.S. Publication No. 2009/0057690, published Mar. 5, 2009, entitled Wafer Level Phosphor Coating Technique For Warm Light Emitting Diodes, and U.S. Publication No. 2011/0121344, published May 26, 2011, entitled Color Correction For Wafer Level White LEDs, the disclosures of which are incorporated by reference.

In particular, the above referenced U.S. Publication No. 2011/0121344 discloses methods that can increase the color uniformity of LEDs that are coated with phosphor on a wafer level. As disclosed therein, a plurality of LEDs may be defined on a wafer. A plurality of spacers are formed on selected ones of the LEDs, which are then coated a wavelength conversion material. The spacers reduce the amount of conversion material over the selected LEDs. This reduction causes the plurality of LED chips to emit a wavelength of light in response to an electrical signal that is within a standard deviation of a target wavelength.

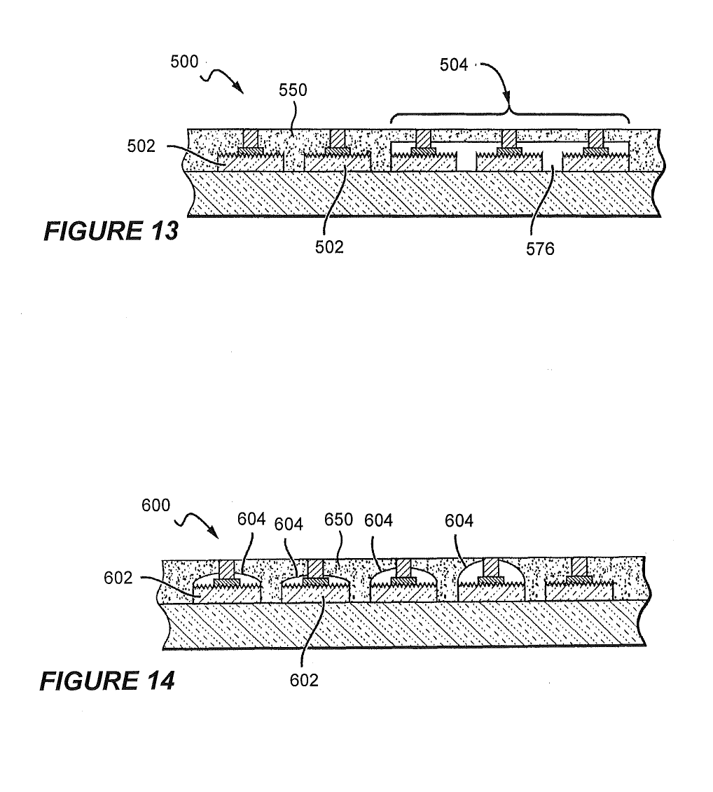

For example, FIG. 13 illustrates a wafer 500 containing LEDs coated with a wavelength conversion material 550. A spacer 504 is formed over a selected plurality of the LEDs 502 on the wafer. The spacer 504 reduces the amount of wavelength conversion material over the selected LEDs, which permits tuning of the wavelength of light emitted by the selected LEDs.

FIG. 14 illustrates a wafer 600 containing LEDs coated with a wavelength conversion material 650. In FIG. 14, spacers 604 may be formed over individual ones of the LEDs 602, and may be formed to have a selected shape. By individually tailoring the amount of wavelength conversion material applied to individual ones of the LEDs, the color uniformity of devices on a particular wafer can be increased, which may increase the number of acceptable devices that can be yielded from the wafer.

Semiconductor substrate wafers having high lumens per wafer have been described herein. In particular embodiments, the semiconductor substrate wafers include LEDs capable of generating in excess of 800,000 lumens per wafer when energized at 350 mA,

Embodiments of the present invention are described herein with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “between”, “below,” “above,” “upper,” “lower,” “horizontal,” “lateral,” “vertical,” “beneath,” “over,” “on,” etc., may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a discrete change from implanted to non-implanted regions. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

In the specification, there have been disclosed embodiments of the invention and, although specific terms are employed, they are used in a generic and descriptive sense only and not for purposes of limitation. The following claim is provided to ensure that the present application meets all statutory requirements as a priority application in all jurisdictions and shall not be construed as setting forth the scope of the present invention.

What is claimed is:

1. An optoelectronic structure, comprising:
a wafer;
a plurality of light emitting diode structures on a surface of the wafer, the light emitting diode structures comprising a common epitaxial structure; and
a coating comprising a wavelength conversion material on the plurality of light emitting diode structures, wherein the light emitting diode structures and the coating are configured to collectively emit white light in response to electrical energy supplied to the light emitting diode structures;
wherein the light emitting diode structures, when singulated, are configured to generate an aggregate light output in excess of 800,000 lumens.

2. The optoelectronic structure of claim 1, wherein the light emitting diode structures are configured to generate an aggregate light output in excess of 825,000 lumens.

3. The optoelectronic structure of claim 2, wherein the light emitting diode structures are configured to generate an aggregate light output in excess of 862,500 lumens.

4. The optoelectronic structure of claim 3, wherein the light emitting diode structures are configured to generate an aggregate light output in excess of 1,000,000 lumens.

5. The optoelectronic structure of claim 4, wherein the light emitting diode structures are configured to generate an aggregate light output in excess of 1,250,000 lumens.

6. The optoelectronic structure of claim 1, wherein the wafer comprises an epitaxial growth wafer on which the common epitaxial structure of the plurality of light emitting diodes is formed.

7. The optoelectronic structure of claim 1, wherein the wafer comprises an a carrier wafer on which the plurality of light emitting diodes are mounted.

8. The optoelectronic structure of claim 1, wherein the plurality of light emitting diode structures comprises at least 7500 light emitting diode structures on the wafer.

9. The optoelectronic structure of claim 8, wherein the plurality of light emitting diode structures comprises at least 9500 light emitting diode structures on the wafer.

10. The optoelectronic structure of claim 1, wherein the plurality of light emitting diode structures represents a device yield of at least about 70% on the wafer.

11. The optoelectronic structure of claim 10, wherein the plurality of light emitting diode structures represents a device yield of at least about 87% on the wafer.

12. The optoelectronic structure of claim 1, wherein each of the plurality of light emitting diode structures emits light within a 4 step MacAdam ellipse of a point on a planckian locus in a two dimensional chromaticity space.

13. The optoelectronic structure of claim 1, wherein the plurality of light emitting diode structures generate light having a color temperature greater than 4500K.

14. The optoelectronic structure of claim 1, wherein the plurality of light emitting diode structures generate light having a color temperature less than 4500K.

15. The optoelectronic structure of claim 1, wherein the plurality of light emitting diode structures have peripheral dimensions less than 1 mm×1 mm.

16. The optoelectronic structure of claim 1, wherein the plurality of light emitting diode structures are configured to generate an aggregate light output in excess of 800,000 lumens at a drive current of 350 mA to respective ones of the plurality of light emitting diode structures.

17. The optoelectronic structure of claim 1, wherein the wafer has a diameter of at least about 100 mm.

18. The optoelectronic structure of claim 1, wherein the wafer has a diameter of at least about 150 mm.

19. An optoelectronic structure, comprising:
a wafer; and
a plurality of light emitting diode structures on a surface of the wafer, wherein the light emitting diode structures are configured to collectively emit an aggregate light output in excess of 800,000 lumens light at a chromaticity region that is within a 4 step MacAdam ellipse of a point on a planckian locus within a two dimensional chromaticity space with a color temperature between 2000K and 8000K in response to electrical energy supplied to the light emitting diode structures.
